(19) United States
(12) Patent Application Publication
(10) Pub. No.: US 2021/0230739 A1
(43) Pub. Date: Jul. 29, 2021

(54) Physical Vapor Deposition Apparatus And Methods With Gradient Thickness Target

(71) Applicant: Applied Materials, Inc., Santa Clara, CA (US)

(72) Inventors: Binni Varghese, Singapore (SG); Ribhu Gautam, Singapore (SG)

(73) Assignee: Applied Materials, Inc., Santa Clara, CA (US)

(21) Appl. No.: 17/152,070

(22) Filed: Jan. 19, 2021

Related U.S. Application Data
(60) Provisional application No. 62/966,175, filed on Jan. 27, 2020.

(51) Int. Cl. C23C 14/34; C23C 14/35; C23C 14/50

(52) U.S. Cl. CPC C23C 14/3407; C23C 14/505; C23C 14/35

(57) ABSTRACT

A physical vapor deposition chamber a first target comprising a bottom surface, a top surface, a cross-sectional thickness defining a first target cross-sectional thickness between the top surface and the bottom surface, a first end and a second end opposite the first end, the cross-sectional thickness at the first end being less than the cross-sectional thickness at the second end. Methods of processing a substrate are also provided.

### CROSS-REFERENCE TO RELATED APPLICATIONS

This application claims priority to U.S. Provisional Application No. 62/966,175, filed Jan. 27, 2020, the entire disclosure of which is hereby incorporated by reference herein.

### TECHNICAL FIELD

The present disclosure relates generally physical vapor deposition chambers, and more particularly, to control of deposition uniformity in physical vapor deposition chambers.

### BACKGROUND

The thickness tolerances on many optical multilayer coating stacks can be very demanding and require precise deposition control and monitoring. In addition to the common problems associated with process control and layer thickness monitoring, particularly for coatings with small error tolerances, large substrates add another difficulty in that the nonuniformity of coating thickness may exceed the error tolerance of the design.

An example of multilayer coating stacks that require a high degree of uniformity is extreme ultraviolet elements. Extreme ultraviolet (EUV) lithography, also known as soft x-ray projection lithography, can be used for the manufacture of 0.0135 micron and smaller minimum feature size semiconductor devices. However, extreme ultraviolet light, which is generally in the 5 to 100 nanometer wavelength range, is strongly absorbed in virtually all materials. For that reason, extreme ultraviolet systems work by reflection rather than by transmission of light. Through the use of a series of mirrors, or lens elements, and a reflective element, or mask blank, coated with a non-reflective absorber mask pattern, the patterned actinic light is reflected onto a resist-coated semiconductor substrate. An EUV reflective element operates on the principle of a distributed Bragg reflector. A substrate supports a multilayer (ML) mirror of 20-80 pairs of alternating layers of two materials, for example, molybdenum and silicon.

The materials that form multilayer stacks of optical coatings such as EUV mask blanks are typically deposited in a physical deposition (PVD) chamber onto a substrate such a low thermal expansion substrate or a silicon substrate. Thin film uniformity across a wafer/substrate is one of the most fundamental requirements for PVD system. Another area of concern is flaking of deposited film from process kit parts in a PVD chamber, including a rotating shield and the target chamber liner. Such flaking causes particle defects on products made in PVD chambers. There remains a need to improve uniformity of deposition of layers of material onto substrates in PVD chambers and to reduce particle generation.

### SUMMARY

In a first aspect of the disclosure pertains to a physical vapor deposition chamber comprising a first target comprising material to be deposited on a substrate, the first target comprising a bottom surface, a top surface, a cross-sectional thickness defining a first target cross-sectional thickness between the top surface and the bottom surface, a first end and a second end opposite the first end, the cross-sectional thickness T₁ at the first end being less than the cross-sectional thickness T₂ at the second end.

In one embodiment, a physical vapor deposition chamber comprises A physical vapor deposition chamber comprising a first target comprising material to be deposited on a substrate, the first target comprising a bottom surface, a top surface, a cross-sectional thickness defining a first target cross-sectional thickness between the top surface and the bottom surface, a first end and a second end opposite the first end, the cross-sectional thickness at the first end being less than the cross-sectional thickness at the second end; and a second target comprising a second target bottom surface, a second target top surface defining a second target cross-sectional thickness between the second target top surface and the second target bottom surface, a second target first end and a second target second end opposite the second target first end, the second target cross-sectional thickness at the second target first end less than the cross-sectional thickness at the second end of the second target, wherein the physical vapor deposition chamber comprises a chamber liner surrounding a substrate support, the chamber liner defining a process area including a center, and substrate support is on center and the first target and the second target are off-center.

In a second aspect of the disclosure pertains to a substrate processing method comprising supporting a substrate having an exposed substrate surface in a physical vapor deposition process chamber on a substrate support; forming a plume of deposition material from at least a first target comprising first target material, the plume of deposition material forming a plume area with respect to the substrate surface, the target comprising a center, a bottom surface and a top surface, and a first target cross-sectional thickness between the top surface and the bottom surface, a first end and a second end opposite the first end, a first end and a second end defining a first target cross-sectional thickness, the first target cross sectional thickness T₁ at the first end is less than the first target cross sectional thickness T₂ at the second end; and depositing a layer from the plume of deposition material on the exposed substrate surface.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a side view of a physical vapor deposition (PVD) chamber according to one or more embodiments;

FIG. 2 is a schematic view of a portion of the PVD chamber shown in FIG. 1 having a variable thickness target;

FIG. 3 is a schematic view of a portion of the PVD chamber shown in FIG. 1 having two variable thickness targets;

FIG. 4 is a schematic view of a portion of the PVD chamber shown in FIG. 1 having two variable thickness targets with a different thickness profile than the targets shown in FIG. 4; and

FIG. 5 is a flow chart showing an exemplary embodiment of a method.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

Those skilled in the art will understand that the use of ordinals such as “first” and “second” to describe process regions do not imply a specific location within the processing chamber, or order of exposure within the processing chamber.

The term “horizontal” as used herein is defined as a plane parallel to the plane or surface of a mask blank, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “on” indicates that there is direct contact between elements. The term “directly on” indicates that there is direct contact between elements with no intervening elements.

EUV reflective elements such as lens elements and EUV mask blanks must have high reflectivity towards EUV light. The lens elements and mask blanks of extreme ultraviolet lithography systems are coated with the reflective multilayer coatings of materials (e.g., molybdenum and silicon). Reflection values of approximately 65% per lens element, or mask blank, have been obtained by using substrates that are coated with multilayer coatings that strongly reflect light within an extremely narrow ultraviolet bandpass, for example, 12.5 to 14.5 nanometer bandpass for 13.5 nanometer EUV light.

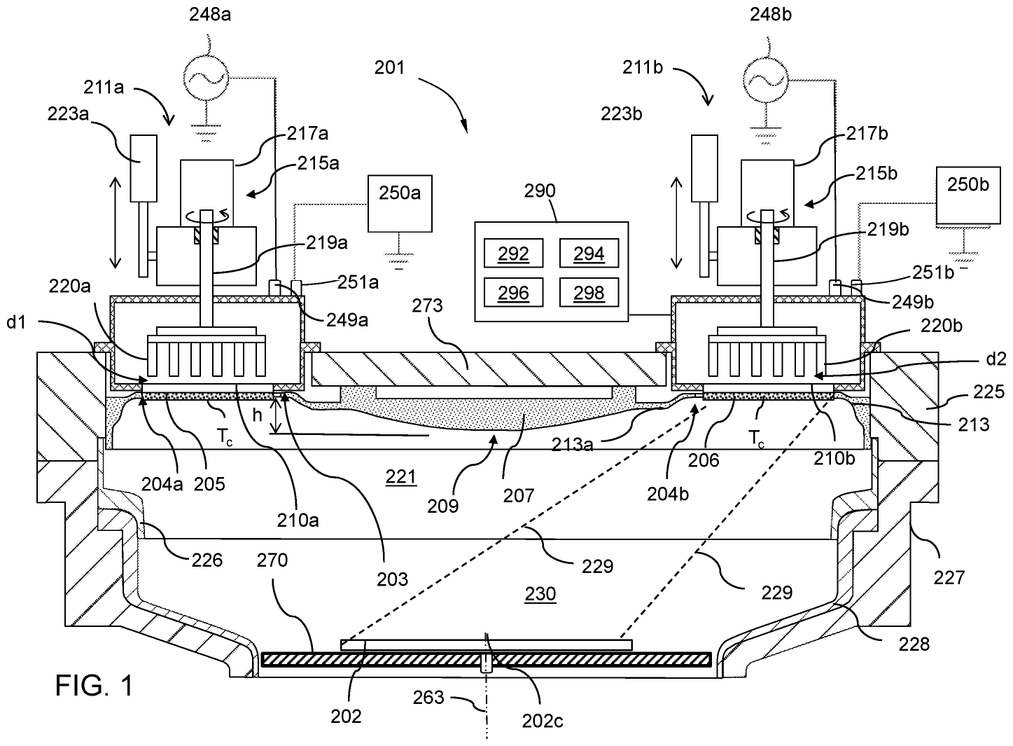

FIG. 1 depicts an example of a PVD chamber 201 in accordance with a first embodiment of the disclosure. PVD chamber 201 includes a plurality of cathode assemblies 211a and 211b. While only two cathode assemblies 211a and 211b are shown in the side view of FIG. 1, a multi-cathode chamber can comprise more than two cathode assemblies, for example, five, six or more than six cathode assemblies arranged around a top lid of the chamber 201. An upper shield 213 is provided below the plurality of cathode assemblies 211a and 211b, the upper shield 213 having two shield holes 204a and 204b to expose targets 205 206 disposed at the bottom of the cathode assemblies 211a and 211b to the interior space 221 of the PVD chamber 201. A middle shield 226 is provided below and adjacent upper shield 213, and a lower shield 228 is provided below and adjacent upper shield 213. In the embodiment shown, there is an upper shield 213, a middle shield 226 and a lower shield 228. However, the present disclosure is not limited to this configuration. The middle shield 226 and the lower shield 228 can be combined into a single shield unit according to one or more embodiments.

A modular chamber body is disclosed in FIG. 1, in which an intermediate chamber body 225 is located above and adjacent a lower chamber body 227. The intermediate chamber body 225 is secured to the lower chamber body 227 to form the modular chamber body, which surrounds lower shield 228 and the middle shield. A top adapter lid 273 is disposed above intermediate chamber body 225 to surround upper shield 213. However, it will be understood that the present disclosure is not limited to a PVD chamber 201 having the modular chamber body as shown in FIG. 1. The intermediate chamber body 225, the lower chamber body 227 and the top adapter lid 273 together form a chamber enclosure which can process substrates under vacuum.

PVD chamber 201 is also provided with a rotating substrate support 270, which can be a rotating substrate support to support the substrate 202. The rotating substrate support 270 can also be heated by a resistance heating system. The PVD chamber 201, which comprises a plurality of cathode assemblies including a first cathode assembly 211a including a first backing plate 291a, is configured to support a first target 205 during a sputtering process and a second cathode assembly 211b including a second backing plate 291b configured to support a second target 205b during a physical vapor deposition or sputtering process.

The specific embodiment of the PVD chamber 201 further comprises an upper shield 213 below the plurality of cathode assemblies 211a, 211b having a first shield hole 204a having a diameter D1 and positioned on the upper shield to expose the first cathode assembly 211a and a second shield hole 204b having a diameter D2 and positioned on the upper shield 213 to expose the second cathode assembly 211b, the upper shield 213 having a substantially flat inside surface 203, except for a region 207 between the first shield hole 204a and the second shield hole 204b. In alternative embodiments, the there is only a first shield hole 204a and not a second shield hole 204b, and thus the shield comprises a single hole.

The upper shield 213 includes a raised area 209 in the region 207 between the first shield hole and the second shield hole, the raised area 209 having a height “H” from the substantially flat inside surface 203 that greater than one centimeter from the flat inside surface 203 and having a length “L” greater than the diameter D1 of the first shield hole 204a and the diameter D2 of the second shield hole 204b, wherein the PVD chamber is configured to alternately sputter material from the first target 205 and the second target 206 without rotating the upper shield 213.

In one or more embodiments, the raised area 209 has a height h so that during a sputtering process, the raised area height h is sufficient to prevents material sputtered from the first target 205 from being deposited on the second target 206 and to prevent material sputtered from the second target 206 from being deposited on the first target 205.

According to one or more embodiments of the disclosure, the first cathode assembly 211a comprises a first magnet spaced apart from the first backing plate 291a at a first distance d1 and the second cathode assembly 211b comprises a second magnet 220b spaced apart from the second backing plate 291b at a second distance d2, wherein the first magnet 220a and the second magnet 220b are movable such that the first distance d1 can be varied and the second distance d2 can be varied. The distance d1 and the distance d2 can be varied by linear actuator 223a to change the distance d1 and linear actuator 223b to change the distance d2. The linear actuator 223a and the linear actuator 223b can comprise any suitable device that can respectively affect linear motion of first magnet assembly 215a and second magnet assembly 215b. First magnet assembly 215a includes rotational motor 217a, which can comprise a servo motor to rotate the first magnet 220a via shaft 219a coupled to rotational motor 217a. Second magnet assembly 215b includes rotational motor 217b, which can comprise a servo motor to rotate the second magnet 220b via shaft 219b coupled to rotational motor 217b. It will be appreciated that the first magnet assembly 215a may include a plurality of magnets in addition to the first magnet 220a. Similarly, the second magnet assembly 215b may include a plurality of magnets in addition to the second magnet 220b.

In one or more embodiments, wherein the first magnet 220a and second magnet 220b are configured to be moved to decrease the first distance d1 and the second distance d2 to increase magnetic field strength produced by the first magnet 220a and the second magnet 220b and to increase the first distance d1 and the second distance d2 to decrease magnetic field strength produced by the first magnet 220a and the second magnet 220b.

In some embodiments, the first target 205 comprises a molybdenum target and the second target 206 comprises a silicon target, and the PVD chamber 201 further comprises a third cathode assembly (not shown) including a third backing plate to support a third target 205c and a fourth cathode assembly (not shown) including a fourth backing plate configured to support a fourth target 205d. The third cathode assembly and fourth cathode assembly according to one or more embodiments are configured in the same manner as the first and second cathode assemblies 211a, 211b as described herein. In some embodiments, the third target 205c comprises a dummy target and the fourth target 205d comprises a dummy target. As used herein, “dummy target” refers to a target that is not intended to be sputtered in the PVD apparatus 201.

Plasma sputtering may be accomplished using either DC sputtering or RF sputtering in the PVD chamber 201. In some embodiments, the process chamber includes a feed structure for coupling RF and DC energy to the targets associated with each cathode assembly. For cathode assembly 211a, a first end of the feed structure can be coupled to an RF power source 248a and a DC power source 250a, which can be respectively utilized to provide RF and DC energy to the first target 205. The RF power source 248a is coupled to RF power in 249a and the DC power source 250a is coupled to DC power in 251a. For example, the DC power source 250a may be utilized to apply a negative voltage, or bias, to the target 206a. In some embodiments, RF energy supplied by the RF power source 248a may range in frequency from about 2 MHz to about 60 MHz, or, for example, non-limiting frequencies such as 2 MHz, 13.56 MHz, 27.12 MHz, 40.68 MHz or 60 MHz can be used. In some embodiments, a plurality of RF power sources may be provided (i.e., two or more) to provide RF energy in a plurality of the above frequencies.

Likewise, for cathode assembly 211b, a first end of the feed structure can be coupled to an RF power source 248b and a DC power source 250b, which can be respectively utilized to provide RF and DC energy to the second target 206. The RF power source 248b is coupled to RF power in 249a and the DC power source 250b is coupled to DC power in 251b. For example, the DC power source 250b may be utilized to apply a negative voltage, or bias, to the second target 206. In some embodiments, RF energy supplied by the RF power source 248b may range in frequency from about 2 MHz to about 60 MHz, or, for example, non-limiting frequencies such as 2 MHz, 13.56 MHz, 27.12 MHz, 40.68 MHz or 60 MHz can be used. In some embodiments, a plurality of RF power sources may be provided (i.e., two or more) to provide RF energy in a plurality of the above frequencies.

While the embodiment shown includes separate RF power sources 248a and 248b for cathode assemblies 211a and 211b, and separate DC power sources 250a and 250b for cathode assemblies 211a and 211b, the PVD chamber can comprise a single RF power source and a single DC power source with feeds to each of the cathode assemblies.

In some embodiments, the methods described herein are conducted in the PVD chamber 201 equipped with a controller 290. There may be a single controller or multiple controllers. When there is more than one controller, each of the controllers is in communication with each of the other controllers to control of the overall functions of the PVD chamber 201. For example, when multiple controllers are utilized, a primary control processor is coupled to and in communication with each of the other controllers to control the system. The controller is one of any form of general-purpose computer processor, microcontroller, microprocessor, etc., that can be used in an industrial setting for controlling various chambers and sub-processors. As used herein, “in communication” means that the controller can send and receive signals via a hard-wired communication line or wirelessly.

Each controller 290 can comprise a processor 292, a memory 294 coupled to the processor 292, input/output devices coupled to the processor 292, and support circuits 296 and 298 to provide communication between the different electronic components of a chamber of the type shown in FIG. 1. The memory 294 includes one or more of transitory memory (e.g., random access memory) and non-transitory memory (e.g., storage) and the memory of the processor may be one or more of readily available memory such as random access memory (RAM), read-only memory (ROM), floppy disk, hard disk, or any other form of digital storage, local or remote. The memory can retain an instruction set that is operable by the processor to control parameters and components of the system. The support circuits are coupled to the processor for supporting the processor in a conventional manner. Circuits may include, for example, cache, power supplies, clock circuits, input/output circuitry, subsystems, and the like.

Processes may generally be stored in the memory as a software routine that, when executed by the processor, causes the process chamber to perform processes of the present disclosure. The software routine may also be stored and/or executed by a second processor that is remotely located from the hardware being controlled by the processor. In one or more embodiments, some or all of the methods of the present disclosure are controlled hardware. As such, in some embodiments, the processes are implemented by software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller has one or more configurations to execute individual processes or sub-processes to perform the method. In some embodiments, the controller is connected to and configured to operate intermediate components to perform the functions of the methods.

Multi-cathode (MC) PVD chambers of the type shown in FIG. 1 are designed deposition of multiple layers and multilayer stacks in a single chamber or co-sputtering of alloys/compound, which are ideal for applications such as optical filters and parts of EUV reflective elements including reflective multilayer stacks and absorber layers.

To fit multiple targets in a multi-cathode PVD chamber, each target 205, 206 has a diameter that is smaller than the substrate 202 on the substrate support 270. This in the substrate radial center 202c being offset at an angle from radial center T_{c} of target 205. In any PVD process, source material starts from a condensed phase (the target) and then transports though a vacuum or low pressure gaseous environment in the form of vapor (a plasma) within a PVD chamber. The vapor then condenses on a substrate to produce a thin film coating. Atoms from the source material (target) are ejected by momentum transfer from a bombarding particle, typically a gaseous ion. During physical vapor deposition, a plume of deposition material is produced, which results in a deposition profile which is uneven, but symmetrically centered about the axis of the sputtering target. In general, the net deposition plume in the region of the substrate is highly non-uniform.

In FIG. 1, a deposition plume can be envisioned by the dashed lines 229 extending from the second target 206 to the substrate 202. The plume area 230 is bounded by dashed lines 229, the second target 206 and the substrate 202 encompasses a plume area 230 during a PVD process.

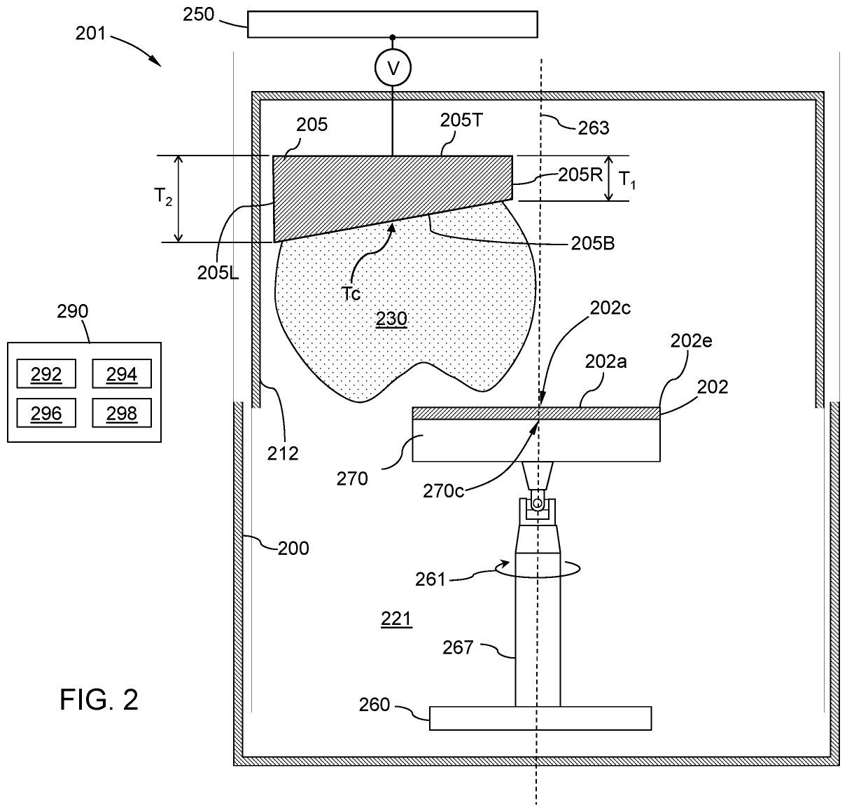

In FIG. 1, the plume area 230 is roughly represented by the dashed lines 229. During a PVD process, the plume area 230 may have a non-uniform shape, such as the shape shown in FIGS. 2-4. It will be appreciated that the shape of the plume area 230 is only roughly approximated as shown in Figures. As will be appreciated however, the plume of deposition material that is deposited on the substrate 202 will often be non-uniform, which will result in non-uniform deposition on a substrate. Thus, the representations provided in the Figures of instant disclosure are not intended to be limiting of the shape of the plume of deposition material formed during a PVD process. It will be appreciated that the shape of the plume in contact with the substrate 202 is non-uniform, which results in non-uniform deposition.

In the manufacture of EUV reflective elements, because of the nature of the multilayer stack and the small feature size, any imperfections in the uniformity of the layers will be magnified and impact the final product. Imperfections on the scale of a few nanometers can show up as printable defects on the finished mask and need to be reduced or eliminated from the surface of the mask blank before deposition of the multilayer stack. The thickness and uniformity of the deposited layers must meet very demanding specifications to not ruin the final completed mask.

An aspect of the disclosure pertains to a physical vapor deposition chamber of the type shown in FIGS. 1-4. FIG. 2 is a schematic view of a portion of the PVD chamber 201 shown in FIG. 1 providing details with respect to the target 205, and various details shown in FIG. 1, such as the chamber enclosure components (i.e., the intermediate chamber body 225, the lower chamber body 227 and the top adapter lid 273) are not shown. Referring to FIG. 2, in one or more embodiments, a physical vapor deposition chamber 201 comprises a rotating substrate support 270, rotated by a rotational motor 260 in communication with a motor driver (not shown) which rotates the substrate support 270 around a rotational axis 263, a first target 205 having a radial center T_{c} positioned off-center from the rotational axis 263 of the substrate support 270. As used herein according to one or more embodiments, off-center with respect to the rotational axis 263 means that the radial center T_{c} of the target 205 is not aligned or coaxial with the rotational axis 263 of the substrate support. The rotational axis 263 of the substrate support 270 is aligned with the radial center 202c of the substrate 202. In some embodiments, a rotational motor 260 is configured to rotate the substrate support 270 in the direction of arrow 261 during a PVD process. In the embodiment shown, a rotational shaft 267 is coupled to a motor 260, which is configured to rotate the rotational shaft 267 and the substrate support 270 during a PVD process. A power source 250 supplies energy to the target 205.

The PVD chamber 201 according to one or more embodiments is controlled by a controller 290, which in some embodiments is used to control any of the processes described herein. The controller 290 sends control signals to activate a DC, RF or pulsed DC power source, and control the power applied to the respective targets during deposition. Furthermore, the controller can sends control signals to adjust the gas pressure in the PVD chamber 201. The controller 290 of some embodiments comprises a processor 292, a memory 294 coupled to the processor 292, input/output devices coupled to the processor 292, and support circuits 296 and 298 to provide communication between the different electronic components of a chamber of the type shown in FIG. 1.

Still referring to FIG. 2, in a specific embodiment of the disclosure, a physical vapor deposition chamber 201 comprises of a first target 205 comprising material 230 to be deposited on a substrate 202. The first target 205 comprises a bottom surface 205B, a top surface 205T, a cross-sectional thickness defining a first target cross-sectional width between the top surface 205T and the bottom surface 205B. The target 205 further comprises a first end 205R and a second end 205L opposite the first end 205R. The cross-sectional thickness T₁ of the first target 205 at the first end 205R is less than the cross-sectional thickness T₂ at the second end 205L of the first target. As shown in FIG. 2, the cross-sectional thickness of the first target is such that the thickness from the first end 205R to the second end 205L is continuously increasing. In other words, T₁ is less than T₂, and the first target 205 has a cross-sectional thickness profile or shape that is wedge-shaped. Stated another way, the first target 205 has a gradient thickness from the first end to the second end.

As shown in FIG. 2, the cross-sectional thickness T₁ of the first target 205 at the first end 205R and the cross-sectional thickness T₂ of the first target 205 at the second end 205L are such that there is a ratio of the cross-sectional thickness T₁ of the first target 205 at the first end 205R to the cross-sectional thickness T₂ of the first target 205 at the second end 205L is in a range of from 1:5 to 1:1.5. In some embodiments, there is a ratio of the cross-sectional thickness T₁ of the first target 205 at the first end 205R to the cross-sectional thickness T₂ of the first target 205 at the second end 205L in a range of from 1:3 to 1:2. In one or more embodiments, the cross-sectional thickness T₁ of the first target 205 at the first end 205R is less than half of the cross-sectional thickness T₂ of the first target 205 at the second end 205L. According to some embodiments, the cross-sectional thickness T₁ of the first target 205 at the first end 205R is in a range of from 0.5 cm to about 2.5 cm and the cross-sectional thickness T₂ of the first target 205 at the second end 205L is in a range of from 1.5 cm to about 5 cm, as long as the cross-sectional thickness T₂ is greater than the cross-sectional thickness T₁.

In one or more embodiments, the cross-sectional thickness profile of the first target 205 as defined by the top surface 205T, the bottom surface 205B and the first end 205R and the second end 205L is in the shape of a right trapezoid. A right trapezoid is a trapezoid that has at least two right angles. The first target 205 in FIG. 2 has a cross-sectional thickness profile which defines a right trapezoid shape.

Still referring to FIG. 2, there is a shield 212 surrounding at least the first end 205R and the second end 205L of the first target 205. As shown in FIG. 2, the physical vapor deposition chamber 201 further comprises a chamber liner 200 surrounding a substrate support 270, and the chamber liner 200 defines an interior space 221 of the PVD chamber 201. In some embodiments, the liner 200 is has a lateral center corresponding to the rotational axis 263 of the substrate support 270, which defines a lateral center of the PVD chamber 201. Thus, axis 263 defines a lateral center of the PVD chamber and the interior space 221 where substrates are processed in the PVD chamber 201. The axis 263 also defines the substrate support center 270c of the substrate support 270. Thus, when a substrate 202 having an end surface and a center 202c is loaded onto the substrate support 270, the center 202c of the wafer is on line with the substrate support center 270c and the rotational axis 263 or the lateral center of the interior space 221 of the PVD chamber. The first target 205 has a center T_{c}, and the first target center Tc is off-line from the substrate center 202c and the substrate support center 270c.

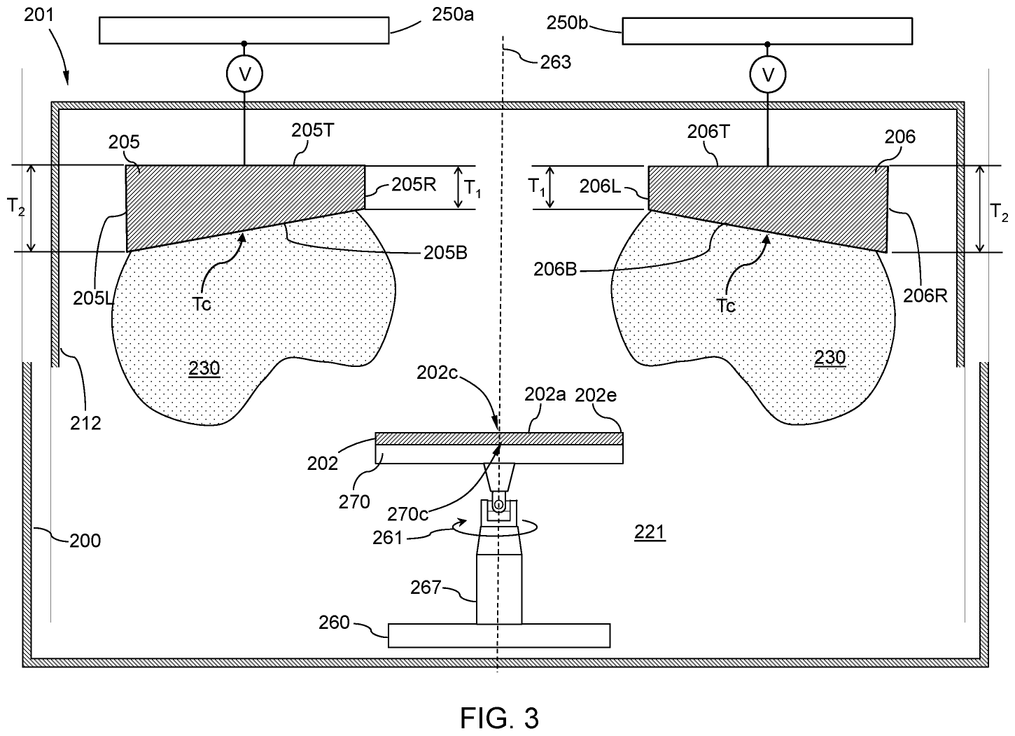

Referring now to FIG. 3, a multi-cathode chamber comprising multiple targets 205, 206 is shown. A first target 205 is laterally spaced from a second target 206. The second target 206 comprises a second target bottom surface 206B, a second target top surface 206T defining a second target cross-sectional thickness between the second target top surface 206T and the second target bottom surface 206B, a second target first end 206L and a second target second end 206R opposite the second target first end 206L. As shown, the second target cross-sectional thickness T₁ at the second target first end 206L is less than the cross-sectional thickness T₂ at the second target second end 206R of the second target 206.

The cross-sectional thickness T₁ of the second target 206 at the first end 206L and the cross-sectional thickness T₂ of the second target 206 at the second end 206R are such that there is a ratio of the cross-sectional thickness T₁ of the second target 206 at the first end 206L to the cross-sectional thickness T₂ of the second target 206 at the second end 206R is in a range of from 1:5 to 1:1.5. In some embodiments, there is a ratio of the cross-sectional thickness T₁ of the second target 206 at the first end 206L to the cross-sectional thickness T₂ of the second target 206 at the second end 206R in a range of from 1:3 to 1:2. In one or more embodiments, the cross-sectional thickness T₁ of the second target 206 at the first end 206L is less than half of the cross-sectional thickness T₂ of the second target 205 at the second end 206R. According to some embodiments, the cross-sectional thickness T₁ of the second target 206 at the first end 206L is in a range of from 0.5 cm to about 2.5 cm and the cross-sectional thickness T₂ of the second target 206 at the second end 206R is in a range of from 1.5 cm to about 5 cm, as long as the cross-sectional thickness T₂ is greater than the cross-sectional thickness T₁. In one or more embodiments, the cross-sectional thickness profile of the second target 206 as defined by the top surface 206T, the bottom surface 2056B and the first end 206L and the second end 206R is in the shape of a right trapezoid. A right trapezoid is a trapezoid that has at least two right angles. The second target 206 in FIG. 3 has a cross-sectional thickness profile which defines a right trapezoid shape.

As shown in FIG. 3, the ends of each of the first target 205 and the second target that are thickest are adjacent to the shield 212. In this instance, the second end 206R of the second target and the second end 205L of the first target 205L are adjacent to the shield 212, and the first end 205R of the first target 205 and the second end 206L of the second target 206 face towards the rotational axis 263 or the center of the interior space 221.

Similar to the portion of the PVD chamber shown in FIG. 2, the portion of the PVD chamber 201 shown in FIG. 3 includes a rotational shaft 267 is coupled to a motor 260, which is configured to rotate the rotational shaft 267 and the substrate support 270 during a PVD process. A power source 250 supplies energy to the target 205. The PVD chamber in FIG. 3 in some embodiment comprises a controller including a processor, a memory coupled to the processor, input/output devices coupled to the processor, and support circuits to provide communication between the different electronic components of a chamber as shown in FIGS. 1 and 2.

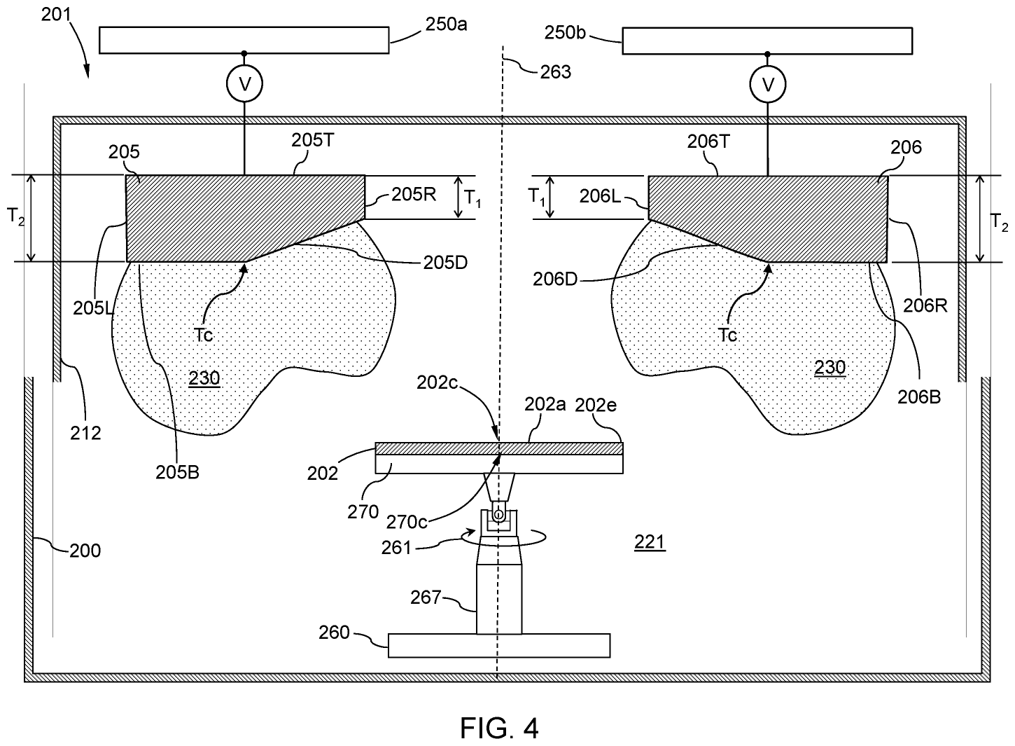

Referring now to FIG. 4, another embodiment is shown, which is similar to the embodiment shown in FIG. 3, and comprises a first target 205 and a second target having a similar arrangement of the first target 205 and the second target 206 in which the thicker end of each of the targets is closer to the shield 212 and the thinner end of each of the targets is closer to the center 263 of the interior space 221 of the PVD chamber 201.

In the embodiment shown in FIG. 4, the first target 205 has a cross-sectional thickness that increases from the first end 205R to a center T_{c} of the first target 205. The first target 205 includes a portion in which the cross-sectional thickness T₂ is constant extending from the second end 205L to the center T_{c} of the first target 205. Likewise, the second target 206 has a cross-sectional thickness that increases from the first end 206L to a center T_{c} of the second target 206. The first target 206 includes a portion in which the cross-sectional thickness T₂ is constant extending from the second end 206R to the center T_{c} of the second target 206.

Similar to the embodiment shown in FIG. 3, in the embodiment in FIG. 4, the cross-sectional thickness T₁ of the first target 205 at the first end 205R and the cross-sectional thickness T₂ of the first target 205 at the second end 205L are such that there is a ratio of the cross-sectional thickness T₁ of the first target 205 at the first end 205R to the cross-sectional thickness T₂ of the first target 205 at the second end 205L is in a range of from 1:5 to 1:1.5. In some embodiments, there is a ratio of the cross-sectional thickness T₁ of the first target 205 at the first end 205R to the cross-sectional thickness T₂ of the first target 205 at the second end 205L in a range of from 1:3 to 1:2. In one or more embodiments, the cross-sectional thickness T₁ of the first target 205 at the first end 205R is less than half of the cross-sectional thickness T₂ of the first target 205 at the second end 205L. According to some embodiments, the cross-sectional thickness T₁ of the first target 205 at the first end 205R is in a range of from 0.5 cm to about 2.5 cm and the cross-sectional thickness T₂ of the first target 205 at the second end 205L is in a range of from 1.5 cm to about 5 cm, as long as the cross-sectional thickness T₂ is greater than the cross-sectional thickness T₁.

A first target 205 is laterally spaced from a second target 206. The second target 206 comprises a second target bottom surface 206B, a second target top surface 206T defining a second target cross-sectional thickness between the second target top surface 206T and the second target bottom surface 206B, a second target first end 206L and a second target second end 206R opposite the second target first end 206L. As shown, the second target cross-sectional thickness T₁ at the second target first end 206L is less than the cross-sectional thickness T₂ at the second target second end 206R of the second target 206.

In the embodiment shown in FIG. 4, the cross-sectional thickness T₁ of the second target 206 at the first end 206L and the cross-sectional thickness T₂ of the second target 206 at the second end 206R are such that there is a ratio of the cross-sectional thickness T₁ of the second target 206 at the first end 206L to the cross-sectional thickness T₂ of the second target 206 at the second end 206R is in a range of from 1:5 to 1:1.5. In some embodiments, there is a ratio of the cross-sectional thickness T₁ of the second target 206 at the first end 206L to the cross-sectional thickness T₂ of the second target 206 at the second end 206R in a range of from 1:3 to 1:2. In one or more embodiments, the cross-sectional thickness T₁ of the second target 206 at the first end 206L is less than half of the cross-sectional thickness T₂ of the second target 205 at the second end 206R. According to some embodiments, the cross-sectional thickness T₁ of the second target 206 at the first end 206L is in a range of from 0.5 cm to about 2.5 cm and the cross-sectional thickness T₂ of the second target 206 at the second end 206R is in a range of from 1.5 cm to about 5 cm, as long as the cross-sectional thickness T₂ is greater than the cross-sectional thickness T₁. In one or more embodiments of multi-cathode chambers, the first target 205 and the second target 206 are each wedge-shaped in cross-section.

Similar to the portion of the PVD chamber shown in FIGS. 2 and 3, the PVD chamber 201 shown in FIG. 4 includes a rotational shaft 267 is coupled to a motor 260, which is configured to rotate the rotational shaft 267 and the substrate support 270 during a PVD process. A power source 250 supplies energy to the target 205. The PVD chamber in FIG. 3 in some embodiment comprises a controller including a processor, a memory coupled to the processor, input/output devices coupled to the processor, and support circuits to provide communication between the different electronic components of a chamber as shown in FIGS. 1 and 2.

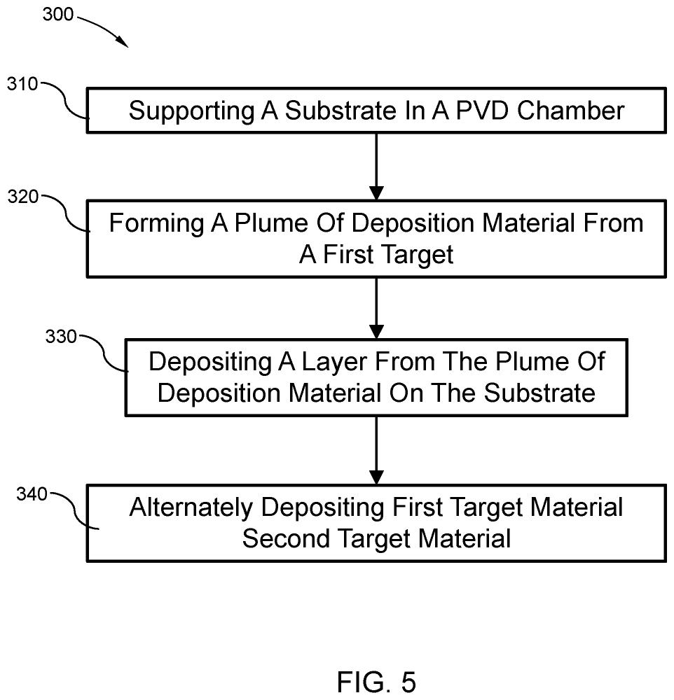

Referring now to FIG. 5, a method 300 comprises supporting a substrate in a PVD chamber as shown at 310 and forming a plume of deposition material from a first target at 320. The method 300 further comprises depositing a layer from the plume of deposition material on the substrate at 330. At 304, the method comprises alternately depositing first target material and second target material on a substrate. Specific method embodiments will now be described. The methods described below can be performed in the chambers shown and described with respect to FIGS. 1-4, and the targets 205, 206 can be configured as shown and described in any of the embodiments described with respect to FIGS. 2-4.

In an exemplary embodiment of the disclosure, a substrate processing method comprises supporting a substrate having an exposed substrate surface in a physical vapor deposition process chamber on a substrate support. The method further comprises forming a plume of deposition material from at least a first target comprising first target material, the plume of deposition material forming a plume area with respect to the substrate surface, the target comprising a center, a bottom surface and a top surface, and a first target cross-sectional thickness between the top surface and the bottom surface, a first end and a second end opposite the first end, a first end and a second end defining a first target cross-sectional thickness, the first target cross sectional thickness T₁ at the first end is less than the first target cross sectional thickness T₂ at the second end. The method further comprises depositing a layer from the plume of deposition material on the exposed substrate surface.

In some embodiments, the method further comprises positioning a shield to surround the first end and the second end of the first target. In one or more embodiments, the method comprise rotating the substrate support about a rotational axis of the substrate support. In some embodiments, the center of the first target is offset from the rotational axis of the substrate support. In some embodiments, the second end of the target is adjacent the shield.

In one or more embodiments, the physical vapor deposition process is performed in a multi-cathode physical vapor deposition chamber and the first target and a second target each have a radial center that is offset from the rotational axis.

In some embodiments, the second target comprises a second target material, a second target bottom surface, a second target top surface defining a second target cross-sectional thickness between the second target top surface and the second target bottom surface, a second target first end and a second target second end opposite the second target first end, the second target cross-sectional thickness at the second target first end less than the second target cross-sectional thickness at the second end of the second target. Such a configuration is shown in FIGS. 3 and 4. The method of some embodiments comprises alternately depositing the first target material from the first target and the second target material from the second target.

It was determined that in PVD chambers, particularly in multi-cathode chambers in which the targets are off center from the substrate and close to the process kit wall, in particular the shield, a thick film deposition forms on a shield and/or on the chamber liner below the targets. At high relative sputtering rates of the target near the process kit wall, the thick films are prone to flaking and causing particulate defects during deposition of an EUV mask blank. It was found that a target with a gradient thickness as shown and described herein with respect to FIGS. 2-4 reduced tilted the sputter profile towards the center of the substrate, and reduced the thick film formation, which will reduce flaking and particulate defects.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A physical vapor deposition chamber comprising:
a first target comprising material to be deposited on a substrate, the first target comprising a bottom surface, a top surface, a cross-sectional thickness defining a first target cross-sectional thickness between the top surface and the bottom surface, a first end and a second end opposite the first end, the cross-sectional thickness T₁ at the first end being less than the cross-sectional thickness T₂ at the second end.

2. The physical vapor deposition chamber of claim 1, wherein the cross-sectional thickness T₁ of the first target at the first end and the cross-sectional thickness T₂ of the first target at the second end are such that there is a ratio of the cross-sectional thickness of the first target at the first end to the cross-sectional thickness of the first target at the second end in a range of from 1:5 to 1:1.5.

3. The physical vapor deposition chamber of claim 1, wherein there is a ratio of the cross-sectional thickness T₁ of the first target at the first end to the cross-sectional thickness T₂ of the first target at the second end is in a range of from 1:3 to 1:2.

4. The physical vapor deposition chamber of claim 1, wherein the cross-sectional thickness T₁ of the first target at the first end is less than half of the cross-sectional thickness T₂ of the first target at the second end.

5. The physical vapor deposition chamber of claim 1, wherein the cross-sectional thickness T₁ of the first target at the first end is in a range of from 0.5 cm to about 2.5 cm and the cross-sectional thickness T₂ of the first target at the second end is in a range of from 1.5 cm to about 5 cm.

6. The physical vapor deposition chamber of claim 1, wherein the cross-sectional thickness of the first target between the first end and the second end defines a right trapezoid shape.

7. The physical vapor deposition chamber of claim 6, wherein there is a ratio of the cross-sectional thickness T₁ of the first target at the first end to the cross-sectional thickness T₂ of the first target at the second end in a range of from 1:5 to 1:1.5.

8. The physical vapor deposition chamber of claim 1, wherein the physical vapor deposition chamber comprises a shield surrounding the first end and the second end of at least the first target.

9. The physical vapor deposition chamber of claim 1, wherein the physical vapor deposition chamber comprises a chamber liner surrounding a substrate support, the chamber liner defining an interior space of the chamber, and substrate support is on center and the first target is off-center.

10. The physical vapor deposition chamber of claim 9, further comprising a second target comprising a second target bottom surface, a second target top surface defining a second target cross-sectional thickness between the second target top surface and the second target bottom surface, a second target first end and a second target second end opposite the second target first end, the second target cross-sectional thickness at the second target first end less than the cross-sectional thickness at the second end of the second target.

11. The physical vapor deposition chamber of claim 10, wherein the first target and the second target are each wedge-shaped in cross-section.

12. A physical vapor deposition chamber comprising:
a first target comprising material to be deposited on a substrate, the first target comprising a bottom surface, a top surface, a cross-sectional thickness defining a first target cross-sectional thickness between the top surface and the bottom surface, a first end and a second end opposite the first end, the cross-sectional thickness at the first end being less than the cross-sectional thickness at the second end; and
a second target comprising a second target bottom surface, a second target top surface defining a second target cross-sectional thickness between the second target top surface and the second target bottom surface, a second target first end and a second target second end opposite the second target first end, the second target cross-sectional thickness at the second target first end less than the cross-sectional thickness at the second end of the second target, wherein the physical vapor deposition chamber comprises a chamber liner surrounding a substrate support, the chamber liner defining a process area including a center, and substrate support is on center and the first target and the second target are off-center.

13. A substrate processing method comprising:
supporting a substrate having an exposed substrate surface in a physical vapor deposition process chamber on a substrate support;
forming a plume of deposition material from at least a first target comprising first target material, the plume of deposition material forming a plume area with respect to the substrate surface, the target comprising a center, a bottom surface and a top surface, and a first target cross-sectional thickness between the top surface and the bottom surface, a first end and a second end opposite the first end, the first target cross sectional thickness T₁ at the first end is less than the first target cross sectional thickness T₂ at the second end; and
depositing a layer from the plume of deposition material on the exposed substrate surface.

14. The method of claim 13, further comprising positioning a shield to surround the first end and the second end of the first target.

15. The method of claim 13, further comprising rotating the substrate support about a rotational axis.

16. The method of claim 15, wherein the center of the first target is offset from the rotational axis of the substrate support.

17. The method of claim 15, wherein the second end of the target is adjacent to the shield.

18. The method of claim 15, wherein the physical vapor deposition process is performed in a multi-cathode physical vapor deposition chamber and the first target and a second target each have a radial center that is offset from the rotational axis.

19. The method of claim 18, wherein the second target comprises a second target material, a second target bottom surface, a second target top surface defining a second target cross-sectional thickness between the second target top surface and the second target bottom surface, a second target first end and a second target second end opposite the second target first end, the second target cross-sectional thickness at the second target first end less than the second target cross-sectional thickness at the second end of the second target.

20. The method of claim 19, further comprising alternately depositing the first target material from the first target and the second target material from the second target.
